(19) United States
(12) Patent Application Publication
(10) Pub. No.: US 2003/0030065 A1
(43) Pub. Date: Feb. 13, 2003

(54) Package for semiconductor photoelectric device

(76) Inventor: Jiahn-Chang Wu, Hsinchu (TW)

Correspondence Address: Hung Chang LIN, 8 Schindler Court, Silver Spring, MD, 20903, US

(21) Appl. No.: 10/228,313

(22) Filed: Oct. 28, 2002

Related U.S. Application Data
(63) Continuation of application No. 09/456,491, filed on Dec. 7, 1999, now abandoned.

(51) Int. Cl. H01L 33/00

(52) U.S. Cl. 257/98

(57) ABSTRACT

An optoelectronic device is placed in a through hole of an upper substrate and mounted on a lower substrate, which is stacked under the upper substrate. The through hole forms a focusing cup for the optoelectronic device. A metallic base plate can be inserted between the optoelectronic device and the lower substrate to enhance light reflection and heat removal. The through hole can be lined with metallic coating to enhance light reflection.

### BACKGROUND OF THE INVENTION

(1) Field of the Invention

This invention is related to semiconductor photoelectric devices, in particular to packages for such devices.

(2) Brief Description of Related Art

Conventional semiconductor photoelectric devices such as light emitting diodes (LED) and laser diodes (LD) have a structure as shown in FIG. 1 or FIG. 2. In the structure shown in FIG. 1, the light emitting device 10 has a top electrode 12 located at the top light emitting surface 16 and another electrode 14 which is the bottom of the device 10. In the structure shown in FIG. 2, the light emitting device 10 has a top electrode 12 located at the center of the light emitting surface 16 and a second electrode, which is the bottom surface 14 of the device 10. The top electrode 12 of the light emitting device 10 shown in FIG. 1 is then connected to a substrate 20 by bonding wire 18 to the printed wiring on substrate 20, while the bottom electrode 14 also makes contact with the printed wiring on the substrate 20 as shown in FIG. 3. Similarly, the top electrode 12 of the light emitting device 10 shown in FIG. 2 is connected to a substrate 20 by bonding wire 18 to the printed wiring on the substrate 20, while the bottom electrode 14 also makes contact with the printed wiring on the substrate 20 as shown in FIG. 4.

The wire bonding process very labor intensive and not cost effective.

### SUMMARY OF THE INVENTION

An object of this invention is to eliminate wire bonding in packaging a semiconductor photoelectric device. Another object of this invention is to package an array of semiconductor photoelectric devices without wire bonding.

These objects are achieved by using a transparent plate to cover the semiconductor photoelectric device. The cover has printed wiring to contact the top electrode or electrodes of the photoelectric device. The transparent cover can let the incident light or emitted light to pass through. The transparent cover presses the photoelectric device against a mother board so that pressure contact is made.

### BRIEF DESCRIPTION OF SEVERAL VIEWS OF THE DRAWINGS

FIG. 1 shows a prior art light emitting device with a corner top electrode.

FIG. 2 shows a prior art light emitting device with a center top electrode.

FIG. 3 shows the device shown in FIG. 1 wire-bonded to a substrate.

FIG. 3 shows the device shown in FIG. 1 wire-bonded to a substrate.

FIG. 4 shows the device shown in FIG. 2 wire-bonded to a substrate.

FIG. 5 shows the structure in packaging a light emitting semiconductor device based on the present invention.

FIG. 6 shows the side view of the present invention.

FIG. 7 shows the top view of an array of semiconductor light emitting devices connected to a common substrate.

FIG. 8 shows the top view of the substrate shown in FIG. 7.

FIG. 9 shows a second embodiment of the present invention where both electrodes of the semiconductor light emitting device are at the top surface of the device.

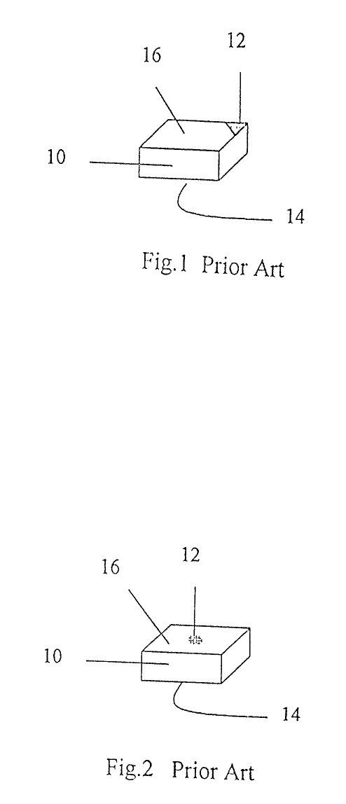

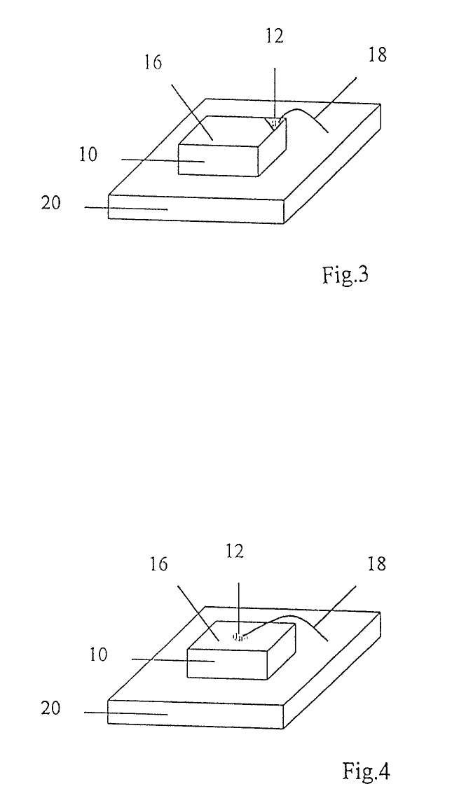

### DETAILED DESCRIPTION OF THE INVENTION

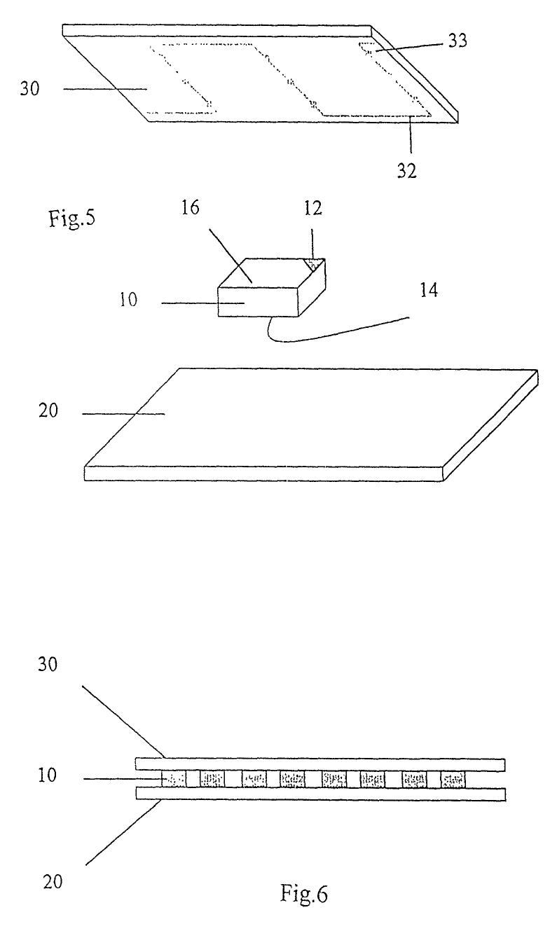

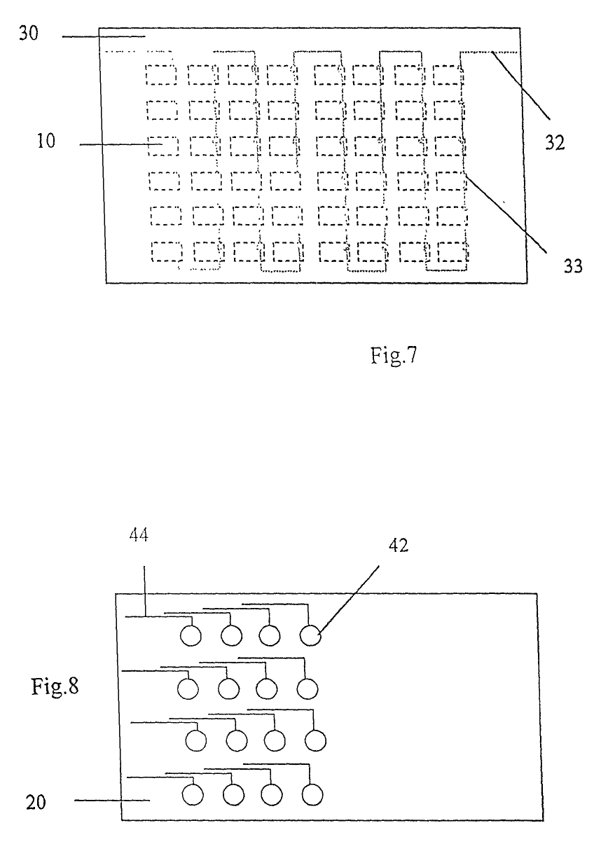

The structure of the present invention is shown in FIG. 5. The semiconductor light emitting device 10 has a top electrode 12, a light emitting surface 16, and a bottom 14 serving as a bottom electrode lying over a substrate 20 as in FIG. 1. A transparent cover 30 is printed with wiring 32. Along the printed wiring 32 are a number of bonding pads 33. The transparent cover 30 presses the light emitting diode 10 against the substrate 20 such that bonding pads 33 make contact with the top electrode 12 of the semiconductor light emitting device 10. Meanwhile the bottom electrode 14 of the light emitting device 10 makes contact with the substrate 20. Thus, the semiconductor light emitting device 10 is sandwiched between the transparent top plate 30 and the substrate 20 as shown in the side view of the structure FIG. 6. By pressing the transparent cover 30 against the bottom substrate 20, pressure contacts are formed both for the top contact 12 with bonding pad 33 and the bottom contact 14 with the substrate.

The transparent cover 30 allows the light emitted from the light emitting device 10 to pass. Transparent material such as glass, quartz, sapphire, plastic, mica, Teflon, fiber, etc. may be used.

A large number of light emitting devices 10 can be sandwiched between the transparent top cover 30 and the bottom substrate 20 as shown in FIG. 8, where an array of light emitting devices 10 connected together through the bonding pads 33 along printed wiring 32 on the top transparent cover 30. The bottom substrate 20 is also lined with an array of pads 42 for contacting the bottom electrodes of the light emitting diodes 10, and serving as a motherboard. These pads 42 can be connected to printed wiring 44.

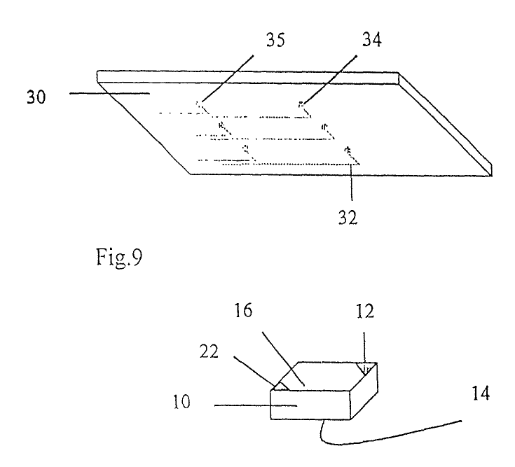

FIG. 9 shows another embodiment of the present invention. In this structure, both electrodes 12 and 22 of the light emitting devices 10 are placed on the light emitting top surface 16. A transparent cover 30 is lined with pads 34 and 35 to contact the electrodes 12 and 22 respectively. These contact pads 34 and 35 are connected to printed wiring 32 of a circuit.

While the foregoing is devoted to the description of light emitting devices, the same invention is applicable to light sensing devices such as photo-diodes, image sensors etc. i.e. semiconductor photoelectric devices in general.

While the preferred embodiments of this invention have been described, it will be apparent to those skilled in the art that various modifications may be made in the embodiments without departing from the spirit of the present invention. Such modifications are all within the scope of this invention.

1. A package for semiconductor photoelectric device, comprising:
a semiconductor photoelectric device having a semiconductor body, two electrodes and a top surface;
at least one of said electrodes being located at the top surface; and
a transparent cover pressing against said top surface,
said transparent cover having a bottom surface printed with underlying electrical wiring for circuit interconnection and bonding pads to contact electrically said electrodes at said top surface.

2. A package as described in claim 1, further comprising a substrate over which said semiconductor photoelectric device presses.

3. A package as described in claim 1, wherein second one of said electrodes is located at the bottom of said semiconductor body.

4. A package as described in claim 2, wherein said substrate has second printed circuit wiring to contact the second one of said electrodes.

5. A package as described in claim 4, wherein said second printed circuit wiring has at least a contact pad to contact the second one of said electrodes.

6. A package as described in claim 1, wherein transparent cover is made of material selected from the group consisting of: glass, quartz, sapphire, plastic, mica, resin, Teflon, and fiber.

7. A package as described in claim 1, wherein both said electrodes are located at the top surface of said semiconductor photoelectric device.

8. A package as described in claim 7, wherein said first printed wiring has pads to contact both said electrodes.

9. A package as described in claim 1, wherein said photoelectric semiconductor device is a light emitting diode.

10. A package as described in claim 1, wherein said semiconductor photoelectric device is a laser diode..

11. A package as described in claim 1, wherein said semiconductor photoelectric device is an image sensor.

12. A package as described in claim, wherein said semiconductor photoelectric device is a photo-diode.

13. A package as described in claim 1, wherein a plurality of said semiconductor photoelectric devices are sandwiched between said transparent and said substrate.

14. A package as described in claim 13, wherein said substrate serves as a motherboard.
